(19) United States
(12) Patent Application Publication
(10) Pub. No.: US 2023/0371270 A1
(43) Pub. Date: Nov. 16, 2023

(54) MEMORY DEVICES

(71) Applicant: SAMSUNG ELECTRONICS CO., LTD., Suwon-si (KR)

(72) Inventors: Hyuncheol KIM, Suwon-si (KR); Yongseok KIM, Suwon-si (KR); Kiheun LEE, Suwon-si (KR); Daewon HA, Suwon-si (KR)

(21) Appl. No.: 18/315,181

(22) Filed: May 10, 2023

(30) Foreign Application Priority Data
May 13, 2022 (KR) 10-2022-0058873

(51) Int. Cl. H10B 51/30; H10B 51/10; H01L 21/28

(52) U.S. Cl. CPC H10B 51/30; H10B 51/10; H01L 29/40111

(57) ABSTRACT

A memory device may include a channel region, a conductive electrode disposed on the channel region, and a data storage structure disposed between the channel region and the conductive electrode. The data storage structure includes a first dielectric layer and a second dielectric layer disposed on the first dielectric layer, the second dielectric layer includes a ferroelectric region and a barrier dielectric region on the ferroelectric region, the ferroelectric region includes a first material, and the barrier dielectric region includes a second material formed by nitriding or oxidizing the first material.

### CROSS-REFERENCE TO RELATED APPLICATION(S)

This application claims priority under 35 U.S.C. § 119 to Korean Patent Application No. 10-2022-0058873 filed on May 13, 2022, in the Korean Intellectual Property Office, the entire disclosure of which is incorporated herein by reference for all purposes.

### BACKGROUND

The present inventive concepts relate to memory devices.

Recently, various new types of memories that may replace dynamic random-access memories (DRAMs) and flash memories have been researched. For example, ferroelectric memories are being researched as non-volatile and high-speed random-access memories (RAMs).

### SUMMARY

Example embodiments may provide memory devices in which reliability and durability may be improved.

According to an example embodiment, a memory device may include a channel region, a conductive electrode disposed on the channel region, and a data storage structure disposed between the channel region and the conductive electrode. The data storage structure may include a first dielectric layer and a second dielectric layer disposed on the first dielectric layer. The second dielectric layer may include a ferroelectric region and a barrier dielectric region on the ferroelectric region. The ferroelectric region may include a first material, and the barrier dielectric region may comprise a compound of the first material and oxygen or a compound of the first material and nitrogen.

According to an example embodiment, a memory device may include a channel region, a conductive electrode facing the channel region, and a data storage structure disposed between the channel region and the conductive electrode. The data storage structure may include a first dielectric layer on the channel region and a second dielectric layer disposed on the first dielectric layer. The second dielectric layer may include a data storage region including a first material and a barrier dielectric region including a second material. The second material may comprise a compound of the first material and oxygen or a compound of the first material and nitrogen. A thickness of the data storage region may be in a range from about 100 angstroms (Å) to about 200 Å, and a thickness of the barrier dielectric region may be in a range from about 5 Å to about 15 Å.

According to an example embodiment, a memory device may include a channel region, a conductive electrode facing the channel region, and a data storage structure disposed between the channel region and the conductive electrode. The data storage structure may include a first dielectric layer in contact with the channel region and a second dielectric layer disposed on the first dielectric layer. The second dielectric layer may include a ferroelectric region and a high-κ region on the ferroelectric region. The ferroelectric region may comprise a first material, and the high-κ region may comprise a compound of the first material and a nitrogen element or a compound of the first material and an oxygen element. A concentration of the nitrogen element or a concentration of the oxygen element may decrease in a direction from the conductive electrode toward the channel region.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a cross-sectional view illustrating a memory device according to an example embodiment of the present invention.

FIG. 2 is a cross-sectional view illustrating a memory device according to an example embodiment of the present invention.

FIG. 3 is a cross-sectional view illustrating a memory device according to an example embodiment of the present invention.

FIG. 4 is a cross-sectional view illustrating a memory device according to an example embodiment of the present invention.

FIGS. 5 and 6 are diagrams illustrating a memory device according to an example embodiment of the present invention.

FIG. 7 is a plan view of a memory device according to an example embodiment of the present invention.

FIGS. 8 and 9 are diagrams illustrating a memory device according to an example embodiment of the present invention.

FIG. 10 is a cross-sectional view of a memory device according to an example embodiment of the present invention.

FIGS. 11 and 12 are diagrams illustrating a memory device according to an example embodiment of the present invention.

FIG. 13 illustrates cross-sectional views of a memory device according to an example embodiment of the present invention.

FIGS. 14 and 15 are diagrams illustrating a memory device according to an example embodiment of the present invention.

FIGS. 16 and 17 are diagrams illustrating a memory device according to an example embodiment of the present invention.

FIGS. 18 and 19 are diagrams illustrating a memory device according to an example embodiment of the present invention.

FIG. 20 is a process flow diagram illustrating a method of forming a memory device according to an example embodiment of the present invention.

FIG. 21 is a process flow diagram illustrating a method of forming a memory device according to an example embodiment of the present invention.

### DETAILED DESCRIPTION

Hereinafter, terms such as “upper”, “middle”, and “lower”, may be replaced with other terms, for example, “first”, “second”, and “third”, to describe elements in the specification. Terms such as “first”, “second”, and “third”, may be used to describe various elements, but these elements are not limited by these terms. These terms are only used to distinguish one element from another. Therefore, a “first element” may be referred to as a “second element” without departing from the teachings of the present disclosure.

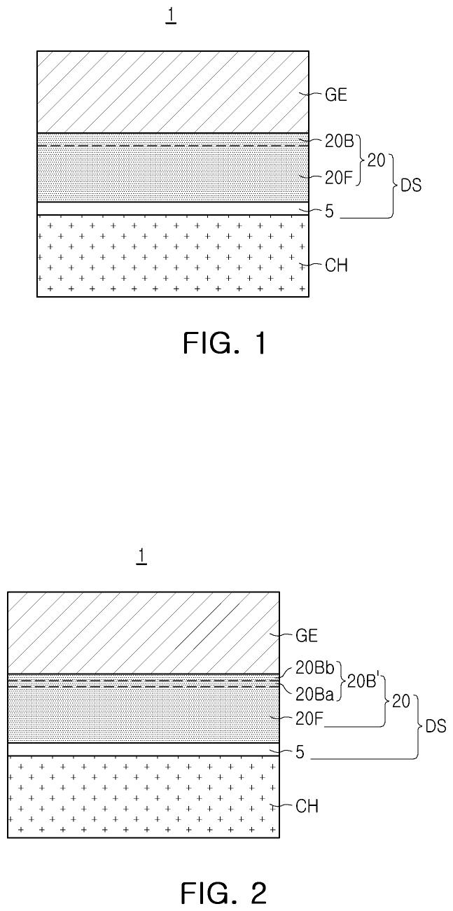

FIG. 1 is a cross-sectional view illustrating a memory device according to an example embodiment of the present invention.

Referring to FIG. 1, a memory device 1 according to an example embodiment may include a first region CH, a second region GE on the first region CH, and a data storage structure DS between the first region CH and the second region GE. The first region CH may be a channel region. For example, the first region CH may be a semiconductor channel region that may be formed of a semiconductor material. The second region GE may be a conductive electrode. For example, the second region GE may be a gate electrode or a word line.

Hereinafter, the first region CH will be referred to as a ‘channel region CH’ and the second region GE will be referred to as a ‘conductive electrode GE’.

The channel region CH may include a material that may be used as a channel of a transistor, for example, a semiconductor material. For example, the channel region CH may be formed of a semiconductor material such as silicon. The channel region CH may be formed of single crystal silicon or polysilicon. However, the channel region CH is not limited to silicon and may also be formed of other semiconductor materials that may be used as the channel region of a transistor. For example, the channel region CH may include an oxide semiconductor material that may be used as a channel region of a transistor or a two-dimensional material having semiconductor properties.

The oxide semiconductor material of the channel region CH may include at least one of various materials, such as Indium Gallium Zinc Oxide (IGZO), Indium Tungsten Oxide (IWO), Indium Tin Gallium Oxide (ITGO), Indium Aluminum Zinc Oxide (IAZO), Indium Gallium Oxide (IGO), Indium Tin Zinc Oxide (ITZO), Zinc Tin Oxide (ZTO), Indium Zinc Oxide (IZO), Zinc Oxide (ZnO), Indium Gallium Silicon Oxide (IGSO), Indium Oxide (InO), Tin Oxide (SnO), Titanium Oxide (TiO), Zinc Oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), and Indium Gallium Silicon Oxide (InGaSiO). The two-dimensional material having semiconductor properties in the channel region CH may include various materials, such as Transition Metal Dichalcogenide (TMD) material and black phosphorous material.

The conductive electrode GE may include doped polysilicon, metal, conductive metal nitride, metal-semiconductor compound, conductive metal oxide, conductive graphene, carbon nanotube, or combinations thereof. For example, the conductive electrode GE may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof, but the present inventive concepts are not limited thereto. The conductive electrode GE may include a single layer or multiple layers of the aforementioned materials.

The data storage structure DS may include a lower (“first”) dielectric layer 5 and an upper (“second”) dielectric layer 20 on the lower dielectric layer 5.

The lower dielectric layer 5 may be in contact with the channel region CH.

The lower dielectric layer 5 may include at least one of various dielectric materials such as silicon oxide, silicon oxynitride, silicon nitride, and high-κ dielectric material. The high-κ dielectric material may include a metal oxide or a metal oxynitride. For example, the high-κ dielectric material may be formed of HfO2, HfSiO, HfSiON, HfTaO, HfTiO, HfZrO, ZrO2, Al2O3, or combinations thereof, but is not limited thereto.

The upper dielectric layer 20 may include a data storage region 20F and a barrier dielectric region 20B on the data storage region 20F.

The thickness of the lower dielectric layer 5 may be in a range from about 8 angstroms (Å) to about 20 Å.

The thickness of the data storage region 20F may be in a range from about 100 Å to about 200 Å.

The thickness of the barrier dielectric region 20B may be in a range from about 1 Å to about 20 Å.

The thickness of the barrier dielectric region 20B may be in a range from about 5 Å to about 15 Å.

The data storage region 20F may include a first material. The first material may comprise a ferroelectric material. Accordingly, the data storage region 20F may be referred to as a ‘ferroelectric region’.

The data storage region 20F, which may be formed of the first (a ferroelectric) material, may have polarization characteristics according to an electric field applied by the conductive electrode GE and may have residual polarization due to dipoles even in the absence of an external electric field. Data may be stored by using the polarization state of the data storage region 20F.

The first material of the data storage region 20F may comprise a ferroelectric material, such as hafnium (Hf)-based compound, zirconium (Zr)-based compound, and Hf—Zr-based compound. For example, the Hf-based compound may include hafnium oxide (HfO)-based ferroelectric material, the Zr-based compound may include zirconium oxide (ZrO)-based ferroelectric material, and the Hf—Zr-based compound may include hafnium zirconium oxide (HZO)-based ferroelectric material.

The first material of the data storage region 20F may include a ferroelectric material doped with various impurities, such as C, Si, Mg, Al, Y, N, Ge, Sn, Gd, La, Sc, and Sr. For example, the first material of the data storage region 20F may include a ferroelectric material in which at least one of HfO2, ZrO2, and HZO is doped with impurities, such as C, Si, Mg, Al, Y, N, Ge, Sn, Gd, La, Sc, and Sr.

The first material of the data storage region 20F is not limited to the above-described material types and may include a material having a ferroelectric property capable of storing data. For example, the first material of the data storage region 20F may comprise a ferroelectric material including, but not limited to, BaTiO₃, PbTiO₃, BiFeO₃, SrTiO₃, PbMgNbO₃, PbMgNbTiO₃, PbZrNbTiO₃, PbZrTiO₃, KNbO₃, LiNbO₃, GeTe, LiTaO₃, KNaNbO₃, BaSrTiO₃, Hf_{0.5}Zr_{0.5}O₂, PbZrₓTi₁₋ₓO₃(0<x<1), BaO₃, SrO₃, TiO₃, Bi₄₋ₓLaₓTi₃O₁₂(0<x<1), SrBi₂Ta₂O₉, Pb₅Ge₅O₁₁, SrB₁₂Nb₂O₉, and YMnO₃.

The barrier dielectric region 20B may contact the conductive electrode GE.

The barrier dielectric region 20B may include the second material. The second material of the barrier dielectric region 20B may include a compound of the first material and a nitrogen element, a compound of the first material and an oxygen element, or a combination thereof. For example, the second material may be formed by nitriding or oxidizing the first material in the data storage region 20F. Here, the nitridation process or the oxidation process may include various types of nitridation and oxidation processes, such as plasma nitridation and plasma oxidation processes. For example, the plasma nitridation process may be a decoupled plasma nitridation process.

In an example, the second material of the barrier dielectric region 20B may include a material formed by nitriding the first material. The nitrogen concentration of the barrier dielectric region 20B may decrease in a direction from the conductive electrode GE toward the channel region CH.

In another example, the second material of the barrier dielectric region 20B may include a material formed by oxidizing the first material. The oxygen concentration of the barrier dielectric region 20B may decrease in a direction from the conductive electrode GE toward the channel region CH.

The data storage region 20F may have a first crystalline phase, and the barrier dielectric region 20B may have a second crystalline phase different from the first crystalline phase. For example, the first crystalline phase of the data storage region 20F may include an orthorhombic phase (O-phase), and the second crystalline phase of the barrier dielectric region 20B may include a monoclinic phase (M-phase).

According to an example embodiment, forming the upper dielectric layer 20 may include forming a ferroelectric layer by a deposition process such as an atomic layer deposition process, and then, forming the barrier dielectric region 20B by changing the film quality of a portion of the ferroelectric layer by a plasma nitridation process or a plasma oxidation process, and using a remaining portion of the ferroelectric layer as the data storage region 20F. Since the data storage region 20F and the barrier dielectric region 20B may be formed from one ferroelectric layer without using different deposition processes, interfaces between the data storage region 20F and the barrier dielectric region 20B may not be detected by an ordinary visual inspection.

The barrier dielectric region 20B may impede a metal element from diffusing into the data storage region 20F from the conductive electrode GE, which may be a gate electrode, and may impede oxygen in the data storage region 20F from diffusing into the conductive electrode GE to form an oxygen vacancy in the data storage region 20F. The barrier dielectric region 20B may be formed to have a thickness of about 1 Å or more and about 20 Å or less and may thereby impede the diffusion of metal elements into the data storage region 20F and impede oxygen vacancies from being formed in the data storage region 20F with the thickness of about 20 Å or less.

Since the barrier dielectric region 20B may be thinner than about 20 Å, an increase in the operating voltage of the memory device 1 for the barrier dielectric region 20B may be significantly reduced.

As the barrier dielectric region 20B may impede the diffusion of metal elements into the data storage region 20F, a gate leakage current may be significantly reduced, and as a result, the memory operation window of the memory device 1 may be improved.

As the barrier dielectric region 20B may impede the oxygen vacancies in the data storage region 20F, the reliability and durability of the memory device 1 may be improved. Therefore, while suppressing the increase in the thickness of the data storage structure DS due to the formation of the barrier dielectric region 20B to about 20 Å or less, the reliability and durability of the memory device 1 may be improved. By providing the upper dielectric layer 20 comprising the data storage region 20F and the barrier dielectric region 20B as described above, while improving the reliability and durability of the memory device 1, the increase in the operating voltage of the memory device 1 may be significantly reduced.

Hereinafter, various modified examples of the elements of the above-described memory device 1 will be described. Various modified examples of the elements of the above-described memory device 1 to be described below will be mainly described with respect to modified or replaced elements. In addition, the elements that may be modified or replaced to be described below may be combined with each other, or combined with the elements described above to configure example embodiments of the memory device 1.

A modified example of the memory device 1 according to an example embodiment of the present invention will be described with reference to FIG. 2. FIG. 2 is a cross-sectional view illustrating a modified example of the memory device 1 according to an example embodiment of the present invention.

In the modified example of the memory device 1, referring to FIG. 2, the barrier dielectric region 20B in FIG. 1 may be replaced with a barrier dielectric region 20B′ comprising a first sub-barrier dielectric region 20Ba and a second sub-barrier dielectric region 20Bb on the first sub-barrier dielectric region 20Ba. The first sub-barrier dielectric region 20Ba may extend from the data storage region 20F.

In an example, the first sub-barrier dielectric region 20Ba may include a third material formed by nitriding the first material of the data storage region 20F, and the second sub-barrier dielectric region 20Bb may include a fourth material formed by oxidizing the third material. Accordingly, the second material of the barrier dielectric region 20B′ may include the third material and the fourth material on the third material.

In another example, the first sub-barrier dielectric region 20Ba may include a fifth material formed by oxidizing the first material of the data storage region 20F, and the second sub-barrier dielectric region 20Bb may include a sixth material formed by nitriding the fifth material. Accordingly, the second material of the barrier dielectric region 203 may include the fifth material and the sixth material on the fifth material.

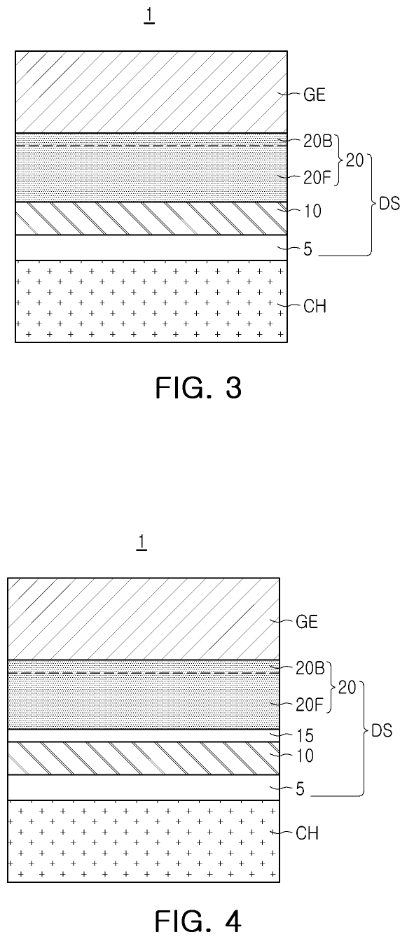

FIG. 3 is a cross-sectional view illustrating a modified example of the memory device 1 according to an example embodiment of the present invention.

In a modified example of the memory device 1, referring to FIG. 3, the data storage structure DS may further include a data storage layer 10 between the upper dielectric layer 20 and the lower dielectric layer 5. The data storage layer 10 may be a charge trap layer. For example, the data storage layer 10 may be formed of a material such as silicon nitride capable of storing data by trapping charges. The memory device 1 may implement a multi-level cell comprising the data storage region 20F and the data storage layer 10.

FIG. 4 is a cross-sectional view illustrating a modified example of the memory device 1 according to an example embodiment of the present invention.

In a modified example of the memory device 1, referring to FIG. 4, the data storage structure DS may further include an intermediate dielectric layer 15 between the data storage layer 10 and the upper dielectric layer 20. The intermediate dielectric layer 15 may include at least one of various dielectric materials such as silicon oxide, silicon oxynitride, silicon nitride, and a high-κ dielectric.

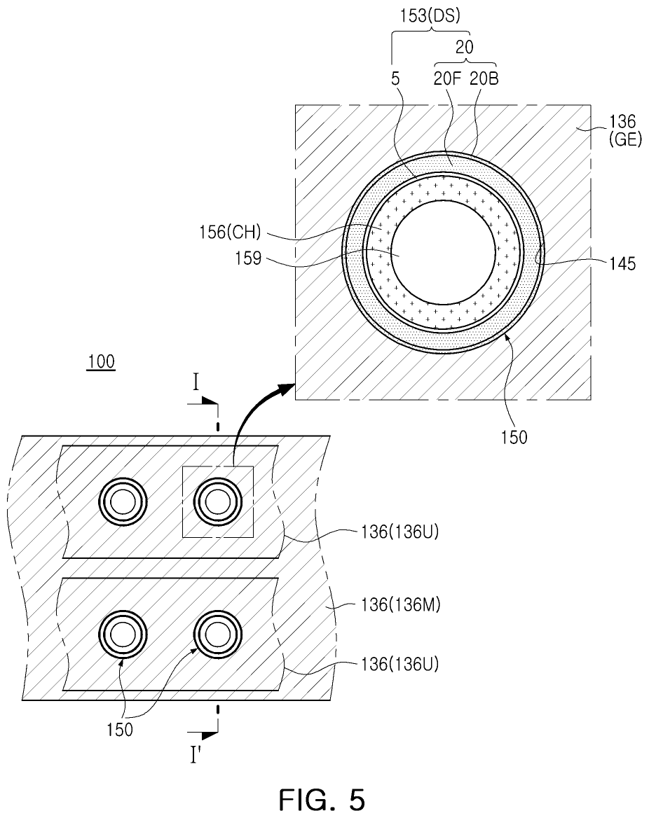

Next, various examples of the memory device 1 will be described with reference to FIGS. 5 to 19. The memory device of various examples described below may include any one of the various data storage structures DS described with reference to FIGS. 1 to 4. For example, the memory device of various examples described below may include the data storage structure DS described in FIG. 1, but examples are not limited thereto. For example, the memory device of various examples described below may include any one of the data storage structures DS described with reference to FIGS. 2 to 4 instead of the data storage structure DS of FIG. 1.

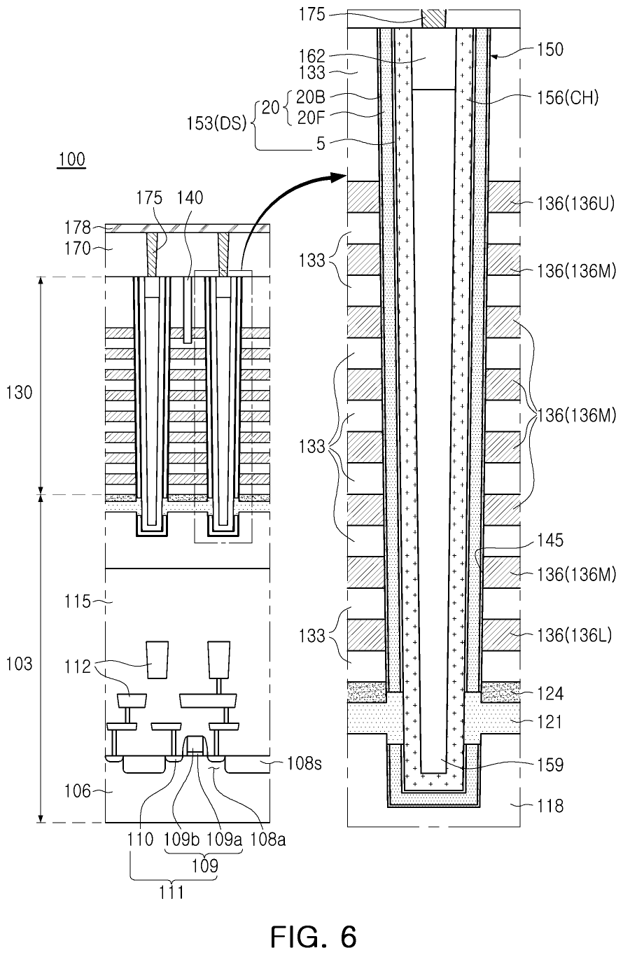

FIGS. 5 and 6 are diagrams illustrating a memory device according to an example embodiment of the present invention. FIG. 5 is a plan view illustrating a memory device 100 according to an example embodiment of the present invention, and FIG. 6 is a cross-sectional view illustrating a region taken along a line I-I′ of FIG. 5.

Referring to FIGS. 5 and 6, the memory device 100, according to an example embodiment of the present invention, may include a lower structure 103, a stack structure 130 on the lower structure 103, an upper insulating layer 170 on the stack structure 130, a vertical memory structure 150 penetrating through (extending in) the stack structure 130, a contact plug 175 penetrating through the upper insulating layer 170 and in contact with the vertical memory structure 150 and, and a bit line 178 on the upper insulating layer 170 and in contact with the contact plug 175.

The lower structure 103 may include a substrate 106, an isolation region 108s defining an active region 108a on the substrate 106, a peripheral circuit 111 on the substrate 106, a circuit wiring structure 112 on the peripheral circuit 111, a peripheral insulating structure 115 covering the peripheral circuit 111 and the circuit wiring structure 112 on the substrate 106, and a plate layer 118 on the peripheral insulating structure 115.

The peripheral circuit 111 may include a transistor including a peripheral gate 109 on the active region 108a and peripheral source/drain regions 110 on both sides of the peripheral gate 109. The peripheral gate 109 may include a peripheral gate dielectric layer 109a and a peripheral gate electrode 109b on the peripheral gate dielectric layer 109a.

The stack structure 130 may include interlayer insulating layers 133 and gate electrodes 136 that are alternately stacked. The gate electrodes 136 may include a lower gate electrode 136L, intermediate gate electrodes 136M on the lower gate electrode 136L, and upper gate electrodes 136U on the intermediate gate electrodes 136M. However, the embodiment of the present invention is not limited thereto. For example, the lower gate electrode 136L comprises one or more lower gate electrodes 136L. Among the interlayer insulating layers 133 and the gate electrodes 136, a lowermost layer and an uppermost layer may be an interlayer insulating layer 133. The lower gate electrode 136L may be a lower selection gate electrode, and the upper gate electrodes 136U may be upper select gate electrodes, for example, string select gate electrodes. The intermediate gate electrodes 136M may be word lines.

The gate electrodes 136 may be the conductive electrodes GE described with reference to FIGS. 1 to 4. For example, the intermediate gate electrodes 136M, which may be word lines, may be the conductive electrodes GE described with reference to FIGS. 1 to 4, and data may be stored in the data storage structure 153 between the channel layer 156 and the intermediate gate electrodes 136M, which may be word lines.

The memory device 100 may further include an upper separation insulating pattern 140 passing through the upper gate electrodes 136U on the intermediate gate electrodes 136M.

The vertical memory structure 150 may be formed in a hole 145 passing through the stack structure 130. The vertical memory structure 150 may include an insulating core pattern 159, a channel layer 156 on an outer side surface of the insulating core pattern 159, a data storage structure 153 on an outer side surface of the channel layer 156, and a pad pattern 162 on an upper surface of the insulating core pattern 159. An outer side surface of an element herein refers to a side surface of the element farther in a horizontal direction from the center of the vertical memory structure 150.

Each of the regions of the channel layer 156 facing the gate electrodes 136 may be the channel region CH described with reference to FIGS. 1 to 4.

The channel layer 156 and the data storage structure 153 may continuously extend from a level lower than the lower gate electrode 136L among the gate electrodes 136 to a level higher than the upper gate electrodes 136U.

The memory device 100 further includes a first horizontal pattern 121 on the plate layer 118 and a second horizontal pattern 124 on the first horizontal pattern 121. The second horizontal pattern 124 may be disposed under the stack structure 130. The vertical memory structure 150 may penetrate through (extend in) the first and second horizontal patterns 121 and 124 and extend into the plate layer 118.

The first horizontal pattern 121 may penetrate through (extend in) the data storage structure 153 and may contact the channel layer 156.

The plate layer 118 may include doped polysilicon, for example, polysilicon having an N-type conductivity. The first horizontal pattern 121 may include doped polysilicon, for example, polysilicon having an N-type conductivity. The second horizontal pattern 124 may include doped polysilicon, for example, polysilicon having an N-type conductivity.

The data storage structure 153 may be any one of the data storage structures DS described with reference to FIGS. 1 to 4. For example, the data storage structure 153 may include the data storage structure DS of FIG. 1 comprising the lower dielectric layer 5 and the upper dielectric layer 20. The lower dielectric layer 5 may contact the channel layer 156. The upper dielectric layer 20 may include the data storage region 20F and the barrier dielectric region 20B as described with reference to FIG. 1. As in the plan view of FIG. 5, the data storage structure 153 may have a ring shape surrounding the channel layer 156, which may also have a ring shape in the plan view.

In the data storage structure 153, the shape of the barrier dielectric region 20B may be changed according to a formation method. For example, after forming the hole 145 penetrating through (extending in) the stack structure 130, the barrier dielectric region 20B may be formed to cover an inner side surface of the hole 145, the data storage region 20F may be formed on an inner side surface of the barrier dielectric region 20B, the lower dielectric layer 5 may be formed on an inner side surface of the data storage region 20F, and the channel layer 156 may be formed on an inner side surface of the lower dielectric layer 5. The barrier dielectric region 20B may continuously extend from a level lower than the lower gate electrode 136L to a level higher than the upper gate electrodes 136U. An inner side surface of an element herein refers to a side surface of the element closer in a horizontal direction to the center of the vertical memory structure 150.

In another example, mold layers may be formed instead of the gate electrodes 136 of the stack structure 130, a hole 145 penetrating through (extending in) the stack structure 130 may be formed, a ferroelectric layer covering the inner side surface of the hole 145 may be formed, the lower dielectric layer 5 may be formed on an inner side surface of the ferroelectric layer, the channel layer 156 may be formed on an inner side surface of the lower dielectric layer 5, and the insulating core pattern 159 and the pad pattern 162 on the upper surface of the insulating core pattern 159 filling the hole 145 may be formed on an inner side surface of the channel layer 156. Then, after removing the mold layers to expose multiple portions of an outer side surface of the ferroelectric layer, the exposed multiple portions of the outer side surface of the ferroelectric layer may be nitridized or oxidized by performing a nitridation process or an oxidation process to form the barrier dielectric regions 20B, and the remaining regions of the ferroelectric layer may be used as the data storage regions 20F. Subsequently, the gate electrodes 136 may be formed in spaces from which the mold layers are removed. Accordingly, the barrier dielectric regions 20B may be formed at the same level in a vertical direction as the gate electrodes 136.

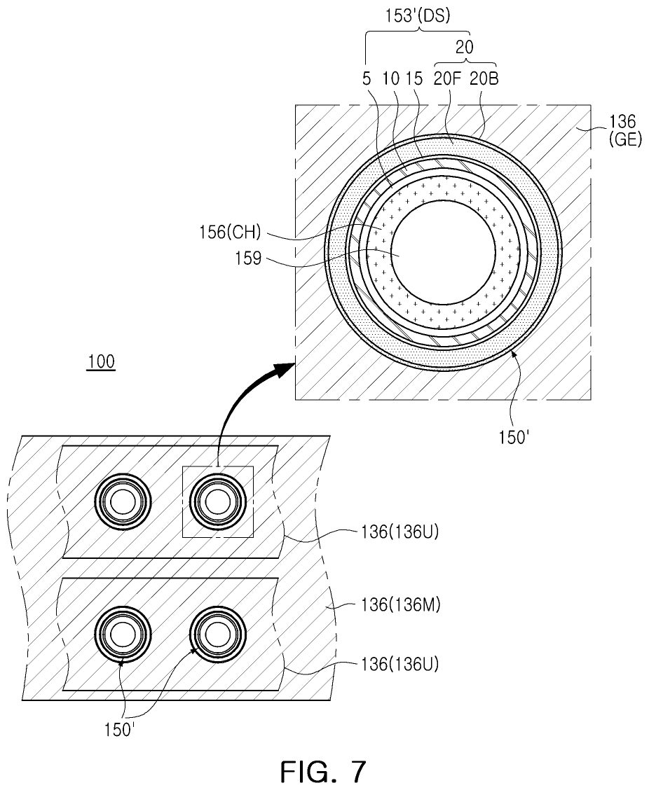

In another example, the data storage structure 153 in FIGS. 5 and 6 may be replaced with a data storage structure 153′, including the data storage structure DS of FIG. 4. The modified data storage structure 153′ is described with reference to FIG. 7. FIG. 7 is a plan view illustrating a modified example of the memory device 100 according to an example embodiment of the present invention.

Referring to FIG. 7, the data storage structure 153 in FIGS. 5 and 6 may be transformed into a data storage structure 153′ including the data storage structure (DS of FIG. 4) as in FIG. 4.

The data storage structure 153′ may include the lower dielectric layer 5 and the upper dielectric layer 20 as in FIGS. 5 and 6.

The data storage structure 153′ may further include the data storage layer 10 between the upper dielectric layer 20 and the lower dielectric layer 5, as described with reference to FIG. 3.

The data storage structure 153′ may further include the intermediate dielectric layer 15 between the data storage layer 10 and the upper dielectric layer 20, as described with reference to FIG. 4.

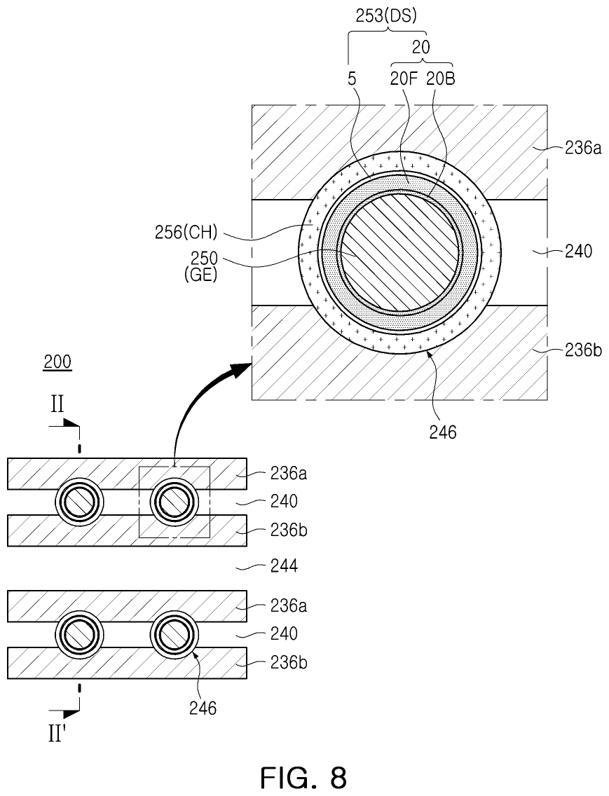

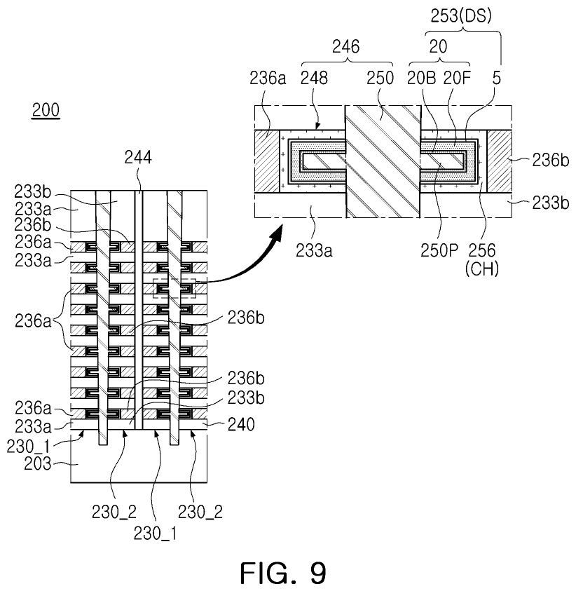

FIGS. 8 and 9 are diagrams illustrating another example of a memory device 200 according to an example embodiment of the present invention. FIG. 8 is a plan view showing the memory device 200, and FIG. 9 is a cross-sectional view illustrating a region taken along a line II-II′ of FIG. 8.

Referring to FIGS. 8 and 9, the memory device 200 according to an example embodiment may include a lower structure 203, a first stack region 230_1 and a second stack region 230_2 disposed on the lower structure 203, and a vertical memory structure 246 passing through between the first stack region 230_1 and the second stack region 230_2. The lower structure 203 may be a substrate on which a peripheral circuit and a peripheral wiring structure are formed.

The first stack region 230_1 may include first interlayer insulating layers 233a and first conductive lines 236a that are alternately and repeatedly stacked in a vertical direction. The second stack region 230_2 may include second interlayer insulating layers 233b and second conductive lines 236b that are alternately and repeatedly stacked in the vertical direction.

The memory device 200 may further include an insulating region 240 between the first stack region 230_1 and the second stack region 230_2. The vertical memory structure 246 may pass through the insulating region 240.

A pair of the first and second stack regions 230_1 and 230_2 may be repeatedly arranged. The memory device 200 may further include an isolation insulating region 244 disposed between the pair of first and second stack regions 230_1 and 230_2 and the other pair of the first and second stack regions 230_1 and 230_2.

The vertical memory structure 246 may include ring patterns 248 in plan view stacked while being spaced apart from each other in the vertical direction and a conductive pillar 250 penetrating through (extending in) the ring patterns 248. The ring patterns 248 may be protruding areas extending toward the first conductive lines 236a or the second conductive lines 236b in a horizontal direction between the first interlayer insulating layers 233a or between the second interlayer insulating layers 233b.

Each of the ring patterns 248 may include a channel region 256 and a data storage structure 253. The channel region 256 may be disposed to surround a side surface of the conductive pillar 250. The data storage structure 253 may be disposed between the channel region 256 and the conductive pillar 250.

The conductive pillar 250 may include protrusions 250P extending into the ring patterns 248. The channel region 256 and the data storage structure 253 may cover an upper surface, a lower surface, and a side surface of each of the protrusions 250P.

The conductive pillar 250 may be the conductive electrode GE described with reference to FIGS. 1 to 4. The channel region 256 may be the channel region CH described with reference to FIGS. 1 to 4.

The data storage structure 253 may be any one of the data storage structures DS described with reference to FIGS. 1 to 4. For example, the data storage structure 253 may include the data storage structure DS as in FIG. 1, comprising the lower dielectric layer 5 and the upper dielectric layer 20. The lower dielectric layer 5 may contact the channel region 256. The upper dielectric layer 20 may include the data storage region 20F and the barrier dielectric region 20B as described with reference to FIG. 1.

In an example embodiment, the conductive pillar 250 may be a gate electrode, the first conductive lines 236a may be bit lines, and the second conductive lines 236b may be source lines.

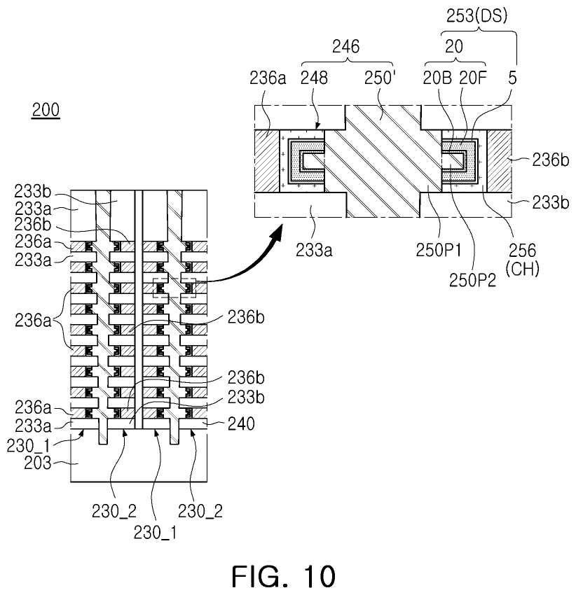

FIG. 10 is a cross-sectional view illustrating a region taken along line II-IP of FIG. 8 in order to explain a modified example of the memory device 200 according to an example embodiment of the present invention.

Referring to FIG. 10, the conductive pillar 250 in FIG. 9 may be replaced with a conductive pillar 250′ containing first protrusions 250P1 and second protrusions 250P2 extending from the first protrusions 250P1 into the ring patterns 248. The first protrusions 250P1 may have substantially the same vertical thickness as the ring patterns 248. The second protrusions 250P2 may have a smaller vertical thickness than the ring patterns 248.

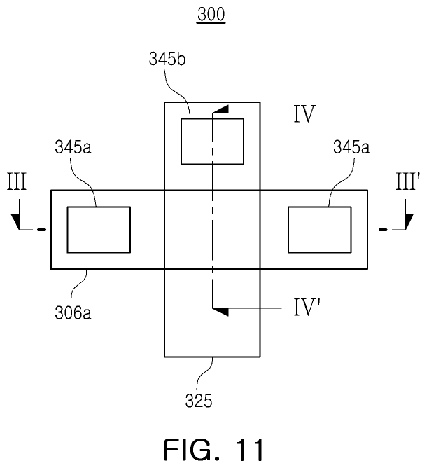

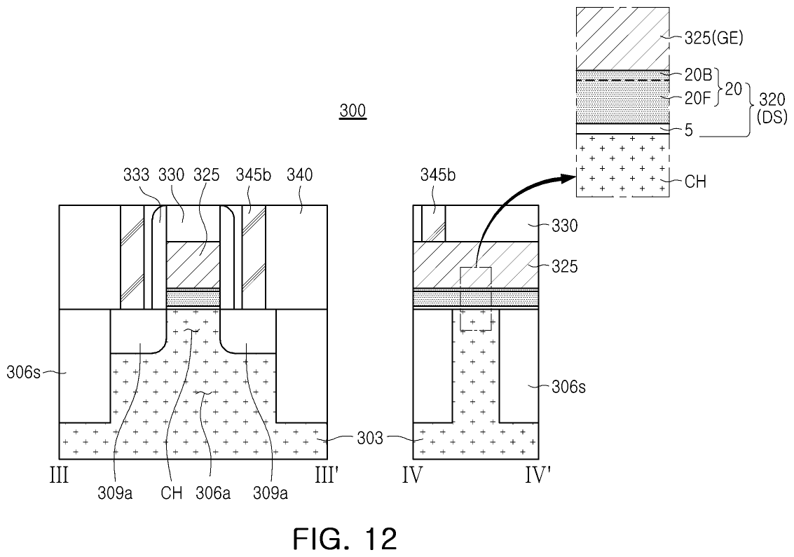

FIGS. 11 and 12 are diagrams illustrating another example of a memory device 300 according to an example embodiment of the present invention. FIG. 11 is a plan view illustrating the memory device 300, and FIG. 12 illustrates cross-sectional views of regions taken along lines and IV-IV′ of FIG. 11.

Referring to FIGS. 11 and 12, the memory device 300 according to an example embodiment may include a substrate 303, an active region 306a in the substrate 303, an isolation region 306s defining the active region 306a in the substrate 303, a gate electrode 325 intersecting the active region 306a in a plan view and extending onto the isolation region 306s, source/drain regions 309a disposed in the active region 306a on both sides of the gate electrode 325, and a data storage structure 320 disposed between the gate electrode 325 and the active region 306a and extending between the gate electrode 325 and the isolation region 306s. The substrate 303 may be a semiconductor substrate.

The active region 306a between the source/drain regions 309a may be the channel region CH described with reference to FIGS. 1 to 4. The gate electrode 325 may be the conductive electrode GE described with reference to FIGS. 1 to 4.

The data storage structure 320 may be any one of the data storage structures DS described with reference to FIGS. 1 to 4. For example, the data storage structure 320 may include the data storage structure DS as in FIG. 1 comprising the lower dielectric layer 5 and the upper dielectric layer 20. The lower dielectric layer 5 may contact the channel region CH. The upper dielectric layer 20 may include the data storage region 20F and the barrier dielectric region 20B as described with reference to FIG. 1. The barrier dielectric region 20B may contact the gate electrode 325.

The memory device 300 may further include an insulating capping layer 330 on an upper surface of the gate electrode 325, insulating spacers 333 on a side surface of the gate electrode 325 and a side surface of the insulating capping layer 330, and an interlayer insulating layer 340 on the isolation region 306s and the active region 306a.

The memory device 300 may further include a source/drain contact plug 345a passing through the interlayer insulating layer 340 and electrically connected to the source/drain regions 309a, and a gate contact plug 345b passing through the insulating capping layer 330 and electrically connected to the gate electrode 325.

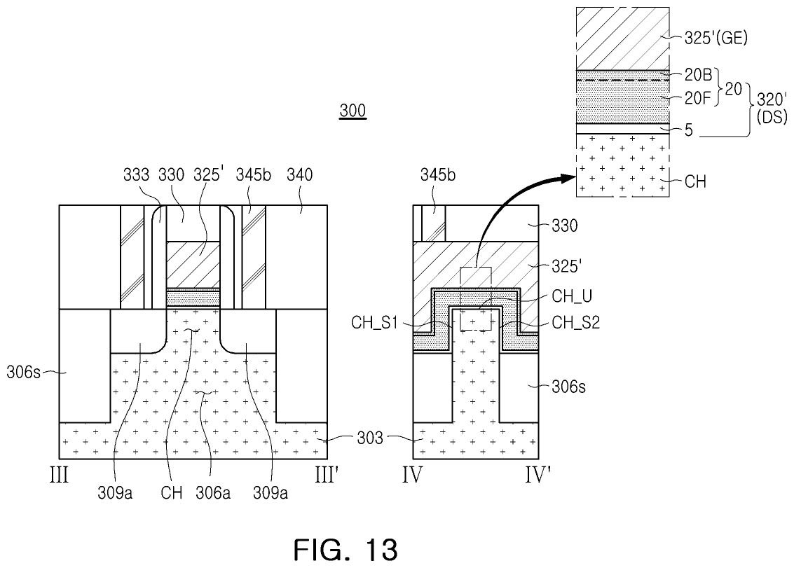

FIG. 13 illustrates cross-sectional views of the regions taken along lines and IV-IV′ of FIG. 11 in order to explain a modified example of the memory device 300 according to an example embodiment of the present invention.

Referring to FIG. 13, the gate electrode 325 in FIG. 12 may be replaced with a gate electrode 325′ covering an upper surface CH U, a first side surface CH_S1 and a second side surface CH_S2 of the channel region CH, and the data storage structure 320 in FIG. 12 may be replaced with a data storage structure 320′ interposed between the gate electrode 325′ and the channel region CH. The first and second side surfaces CH_S1 and CH_S2 of the channel region CH may face each other. Accordingly, the gate electrode 325′ may cover three surfaces of the channel region CH.

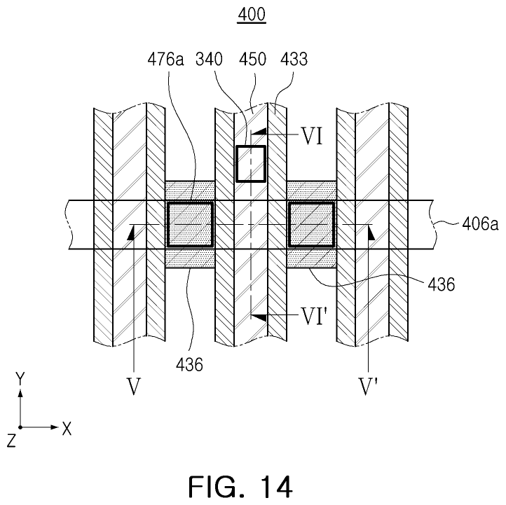

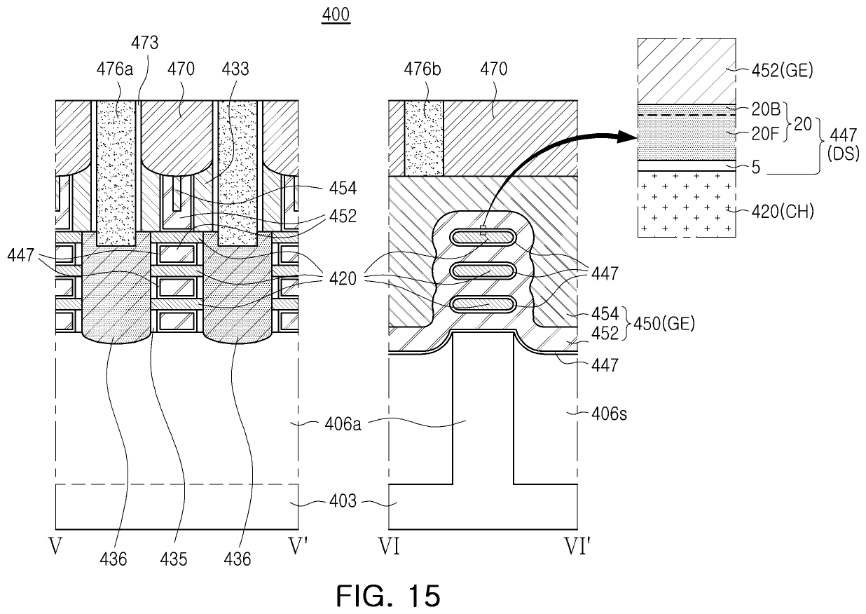

FIGS. 14 and 15 are diagrams illustrating another example of a memory device 400 according to an example embodiment of the present invention. FIG. 14 is a plan view illustrating the memory device 400 and FIG. 15 illustrates cross-sectional views of regions taken along lines V-V and VI-VI′ of FIG. 14.

Referring to FIGS. 14 and 15, The memory device 400 according to an example embodiment may include a substrate 403, an active fin 406a on the substrate 403, and an isolation region 406s on a side surface of the active fin 406a. The substrate 403 may be a semiconductor substrate. For example, the substrate 403 may be a single crystal semiconductor substrate that may be formed of a semiconductor material such as silicon. The isolation region 406s may be formed of an insulating material such as silicon oxide. The active fins 406a may have a line shape or a bar shape extending in a first direction X. The first direction X may be parallel to the upper surface of the substrate 403.

The memory device 400 may include source/drain regions 436 spaced apart from each other in the first direction X on the active fin 406a, a plurality of channel layers 420 stacked while being spaced apart from each other in a vertical direction Z on the active fin 406a and disposed between the source/drain regions 436, a gate electrode 450 that intersects the active fin 406a and extends in a second direction Y and surrounds the plurality of channel layers 420, respectively, a data storage structure 447 including portions interposed between the gate electrode 450 and the plurality of channel layers 420 and a portion covering a lower surface of the gate electrode 450.

The plurality of channel layers 420 may be formed of a semiconductor material. For example, the plurality of channel layers 420 may be formed of a silicon material. In an example embodiment, the plurality of channel layers 420 may include three channel layers stacked while being spaced apart from each other in the vertical direction Z, but the embodiment is not limited thereto. For example, the plurality of channel layers 420 may include four or more channel layers stacked while being spaced apart from each other in the vertical direction Z.

The gate electrode 450 may include multiple electrode layers. For example, the gate electrode 450 may include a first electrode layer 452 in contact with the data storage structure 447 and a second electrode layer 454 on the first electrode layer 452. The gate electrode 450 may be formed by a combination of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, and carbon nanotubes. The first and second electrode layers 452 and 454 may include different conductive materials.

The memory device 400 may further include first insulating spacers 433 on side surfaces of the gate electrode 450, an insulating capping layer 470 on the gate electrode 450 and the first insulating spacers 433, source/drain contact plugs 476a on the source/drain regions 436, gate contact plugs 476b on the gate electrode 450, and an insulating spacer 473 in contact with side surfaces of the source/drain contact plugs 476a.

The plurality of channel layers 420 may include the channel region CH described with reference to FIGS. 1 to 4, and the gate electrode 450 may be the conductive electrode GE described with reference to FIGS. 1 to 4.

The data storage structure 447 may be any one of the data storage structures DS described with reference to FIGS. 1 to 4. For example, the data storage structure 447 may include the data storage structure DS as in FIG. 1, comprising the lower dielectric layer 5 and the upper dielectric layer 20. The lower dielectric layer 5 may contact the channel region CH. The upper dielectric layer 20 may include the data storage region 20F and the barrier dielectric region 20B as described with reference to FIG. 1. The barrier dielectric region 20B may contact the first electrode layer 452 of the gate electrode 450.

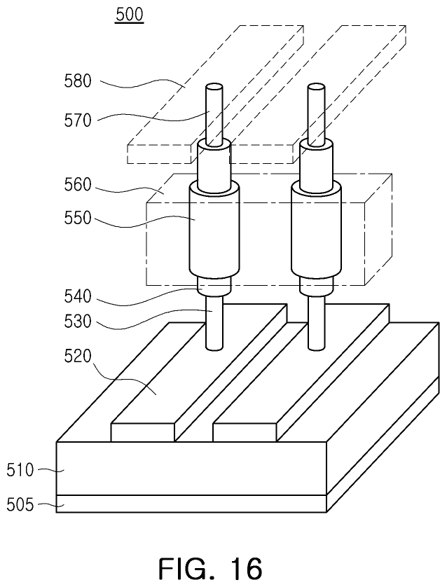

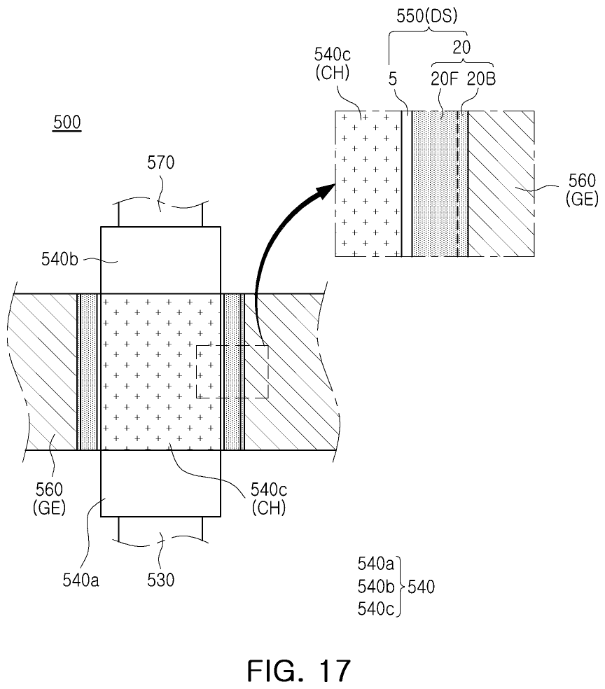

FIGS. 16 and 17 are diagrams illustrating another example of a memory device 500 according to an example embodiment of the present invention. FIG. 16 is a perspective view illustrating the memory device 500, and FIG. 17 is a cross-sectional view illustrating some elements of FIG. 16.

Referring to FIGS. 16 and 17, the memory device 500 according to an example embodiment may include a substrate 505, a circuit region 510 on the substrate 505, a first conductive line 520 on the circuit region 510, a gate electrode 560 extending in a direction crossing the first conductive line 520 on the first conductive line 520, a vertical semiconductor pattern 540 penetrating through (extending in) the gate electrode 560, a first contact plug 530 between the vertical semiconductor pattern 540 and the first conductive line 520, a second conductive line 580 extending in a direction crossing the gate electrode 560 on the vertical semiconductor pattern 540, a second contact plug 570 between the vertical semiconductor pattern 540 and the second conductive line 580, and a data storage structure 550 between the gate electrode 560 and the vertical semiconductor pattern 540.

The gate electrode 560 may be a word line, any one of the first conductive line 520 and the second conductive line 580 may be a bit line, and the other thereof may be a source line.

The vertical semiconductor pattern 540 may include a lower source/drain 540a, an upper source/drain 540b on the lower source/drain 540a, and a channel region 540c between the lower source/drain 540a and the upper source/drain 540b.

The channel region 540c may be the channel region CH described with reference to FIGS. 1 to 4, and the gate electrode 560 may be the conductive electrode GE described with reference to FIGS. 1 to 4.

The data storage structure 550 may be any one of the data storage structures DS described with reference to FIGS. 1 to 4. For example, the data storage structure 550 may include the data storage structure DS as in FIG. 1, comprising the lower dielectric layer 5 and the upper dielectric layer 20. The lower dielectric layer 5 may contact the channel region 540c (CH). The upper dielectric layer 20 may include the data storage region 20F and the barrier dielectric region 20B as described with reference to FIG. 1. The barrier dielectric region 20B may contact the gate electrode 560.

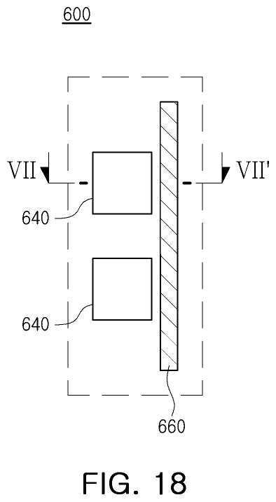

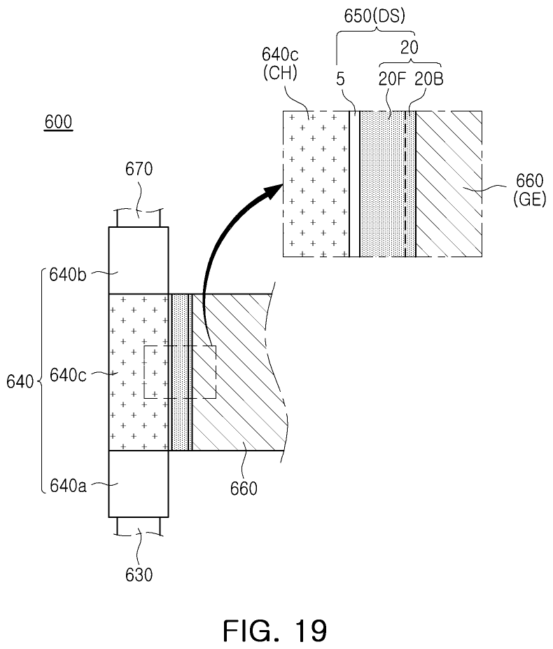

The channel region 540c may be a vertical channel region. The data storage structure 550 and the gate electrode 560 may cover the entire outer side surface of the channel region 540c, but the embodiment is not limited thereto. For example, the data storage structure 550 and the gate electrode 560 may be deformed to cover some outer side surfaces of the channel region 540c. The example in which the data storage structure 550 and the gate electrode 560 are deformed to cover some outer side surfaces of the channel region 540c is described with reference to FIGS. 18 and 19. FIG. 18 is a plan view showing another example of a memory device 600 according to an example embodiment of the present invention, and FIG. 19 is a cross-sectional view illustrating a part of a region taken along VII-VII′ of FIG. 18.

Referring to FIGS. 18 and 19, the memory device 600 according to an example embodiment may include a vertical semiconductor pattern 640, a gate electrode 660 extending to face some side surfaces of the vertical semiconductor pattern 540, a first contact plug 630 under the vertical semiconductor pattern 640, a second contact plug 670 on the vertical semiconductor pattern 640, and a data storage structure 650 between the gate electrode 660 and the vertical semiconductor pattern 640.

The vertical semiconductor pattern 640 may include a lower source/drain 640a, an upper source/drain 640b on the lower source/drain 640a, and a channel region 640c between the lower source/drain 640a and the upper source/drain 640b.

The channel region 640c may be the channel region CH described with reference to FIGS. 1 to 4, and the gate electrode 660 may be the conductive electrode GE described with reference to FIGS. 1 to 4. The data storage structure 650 may be any one of the data storage structures DS described with reference to FIGS. 1 to 4. For example, the data storage structure 650 may include the data storage structure DS as in FIG. 1, comprising the lower dielectric layer 5 and the upper dielectric layer 20. The lower dielectric layer 5 may contact the channel region 640c (CH). The upper dielectric layer 20 may include the data storage region 20F and the barrier dielectric region 20B as described with reference to FIG. 1. The barrier dielectric region 20B may contact the gate electrode 660.

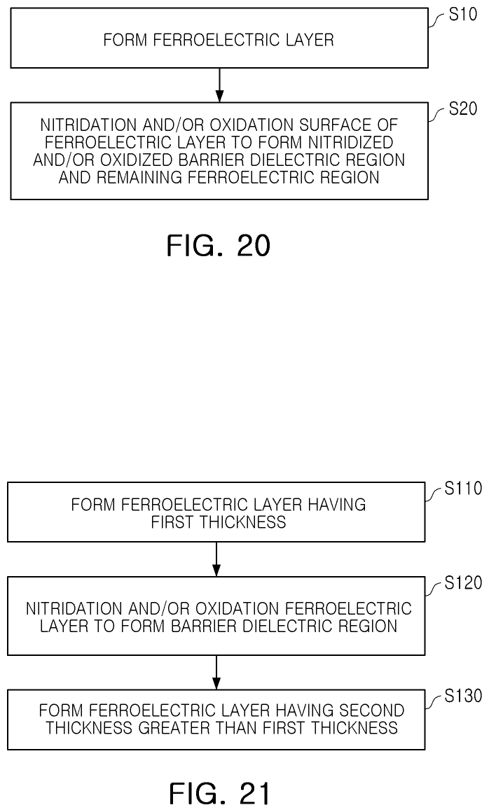

Next, methods of forming the data storage region 20F and the barrier dielectric region 20B of the data storage structure DS in the above-described embodiments are described in FIGS. 20 and 21. FIG. 20 is a process flow diagram illustrating an example of a method of forming the data storage region 20F and the barrier dielectric region 20B of the data storage structure DS in the above-described embodiments. FIG. 21 is a process flow diagram illustrating another example of a method of forming the data storage region 20F and the barrier dielectric region 20B of the data storage structure DS in the above-described embodiments.

In an example, with reference to FIG. 20, forming the data storage structure DS may include forming a ferroelectric layer (S10), and nitriding and/or oxidizing the surface of the ferroelectric layer to form nitridized and/or oxidized barrier dielectric region and a remaining ferroelectric region (S20). For example, forming the upper dielectric layer 20 in FIG. 1 of the data storage structure DS may include forming a ferroelectric layer by a deposition process such as an atomic layer deposition process, and then, forming the barrier dielectric region 20B in FIG. 1 by changing the film quality of a surface portion of the ferroelectric layer by a plasma nitridation process or a plasma oxidation process and using a remaining portion of the ferroelectric layer as the data storage region 20F in FIG. 1. Accordingly, the data storage region 20F and the barrier dielectric region 20B may be formed from one ferroelectric layer.

In another example, referring to FIG. 21, forming the data storage structure DS may include forming a ferroelectric layer of a first thickness (S110), forming a barrier dielectric region by nitriding and/or oxidizing the ferroelectric layer (S120), and forming a ferroelectric region having a second thickness greater than the first thickness (S130). The ferroelectric region may be the data storage region 20F in FIG. 1, and the barrier dielectric region may be the barrier dielectric region 20B in FIG. 1.

As set forth above, according to example embodiments, the barrier dielectric region may be formed by changing a film quality of a portion of the ferroelectric layer by a nitridation process or an oxidation process, and a remaining portion of the ferroelectric layer may be used as the data storage region. This barrier dielectric region may impede diffusion of metal elements from the gate electrode into the data storage region and impede oxygen in the data storage region from diffusing into the gate electrode and oxygen vacancies from being formed in the data storage region. The barrier dielectric region may be formed to have a thickness of about 20 Å or less, and at the thickness of about 20 Å or less, the barrier dielectric region may impede diffusion of metal elements into the data storage region and formation of oxygen vacancies in the data storage region. Therefore, the increase in the thickness of the data storage structure due to the formation of the barrier dielectric region may be significantly reduced, while the reliability and durability of the memory device may be improved.

While example embodiments have been illustrated and described above, it will be apparent to those skilled in the art that modifications and variations could be made without departing from the scope of the present inventive concepts as defined by the appended claims.

What is claimed is:

1. A memory device comprising:
a channel region;
a conductive electrode on the channel region; and
a data storage structure between the channel region and the conductive electrode,
wherein the data storage structure includes a first dielectric layer and a second dielectric layer on the first dielectric layer,
the second dielectric layer includes a ferroelectric region and a barrier dielectric region on the ferroelectric region,
the ferroelectric region includes a first material, and
the barrier dielectric region includes a second material comprising a compound of the first material and oxygen or a compound of the first material and nitrogen.

2. The memory device of claim 1, wherein the first dielectric layer is in contact with the channel region, and
the barrier dielectric region is in contact with the conductive electrode.

3. The memory device of claim 1, wherein the ferroelectric region comprises the first material in a first crystalline phase, and
the barrier dielectric region comprises the second material in a second crystalline phase different from the first crystalline phase.

4. The memory device of claim 3, wherein the first crystalline phase includes an orthorhombic phase (O-phase), and
the second crystalline phase includes a monoclinic phase (M-phase).

5. The memory device of claim 1, wherein the second material of the barrier dielectric region comprises a nitride of the first material, and
a nitrogen concentration of the barrier dielectric region decreases in a direction from the conductive electrode toward the channel region.

6. The memory device of claim 1, wherein the second material of the barrier dielectric region comprises an oxide of the first material, and
an oxygen concentration of the barrier dielectric region decreases in a direction from the conductive electrode toward the channel region.

7. The memory device of claim 1, wherein the barrier dielectric region includes a first sub-barrier dielectric region and a second sub-barrier dielectric region on the first sub-barrier dielectric region.

8. The memory device of claim 7, wherein the first sub-barrier dielectric region includes a third material comprising a nitride of the first material, and
the second sub-barrier dielectric region includes a fourth material comprising an oxide of the third material.

9. The memory device of claim 7, wherein the first sub-barrier dielectric region includes a third material comprising an oxide of the first material, and
the second sub-barrier dielectric region includes a fourth material comprising a nitride of the third material.

10. The memory device of claim 1, wherein the data storage structure further comprises a data storage layer between the first dielectric layer and the second dielectric layer.

11. The memory device of claim 10, wherein the data storage structure further comprises an intermediate dielectric layer between the data storage layer and the second dielectric layer.

12. The memory device of claim 1, further comprising:
a substrate; and
a semiconductor pattern on the substrate,
wherein the semiconductor pattern includes a first source/drain region, a second source/drain region farther than the first source/drain region from the substrate, and the channel region between the first source/drain region and the second source/drain region,
the conductive electrode is on a side surface of the semiconductor pattern, and
the data storage structure is between the side surface of the semiconductor pattern and the conductive electrode.

13. The memory device of claim 1, further comprising:
a source region and a drain region spaced apart from each other on a substrate,
wherein the channel region is between the source region and the drain region,
the conductive electrode is on a first surface of the channel region, a second surface of the channel region perpendicular to the first surface of the channel region, and a third surface of the channel region perpendicular to the first surface of the channel region, and
the second and third surfaces of the channel region are opposite surfaces of the channel region.

14. The memory device of claim 1, further comprising:
a source region and a drain region on a substrate,
wherein the channel region is a first channel region of a plurality of channel regions that are included in respective active layers between the source region and the drain region and spaced apart from each other in a vertical direction perpendicular to an upper surface of the substrate,
the conductive electrode encloses the active layers, and
the data storage structure is a first data storage structure of a plurality of data storage structures between the active layers and the conductive electrode.

15. The memory device of claim 1, further comprising:
a substrate;
a stack structure on the substrate, including interlayer insulating layers and gate electrodes stacked alternately and repeatedly in a vertical direction; and
a vertical memory structure extending in the stack structure in the vertical direction,
wherein the vertical memory structure includes:
an insulating core pattern;
a channel layer on an outer side surface of the insulating core pattern; and
a pad pattern on an upper surface of the insulating core pattern,
wherein each of the gate electrodes includes the conductive electrode,
the channel region is a first channel region of a plurality of channel regions having the gate electrodes thereon,
the channel layer includes the channel regions,
the data storage structure is on an outer side surface of the channel layer,
the data storage structure includes a lower region lower than a lowermost one of the gate electrodes and an upper region higher than an uppermost one of the gate electrodes, and
the data storage structure continuously extends from the lower region to the upper region in the vertical direction.

16. The memory device of claim 1, wherein the memory device includes,
a substrate;
a stack structure on the substrate; and
a vertical memory structure extending in the stack structure in a vertical direction,
wherein the stack structure includes interlayer insulating layers and conductive lines alternately and repeatedly stacked in the vertical direction,
the vertical memory structure includes the conductive electrode,
the vertical memory structure further includes protruding areas extending toward the conductive lines in a horizontal direction between the interlayer insulating layers,
each protruding area comprises a portion of the conductive electrode, the data storage structure on the portion of the conductive electrode, and the channel region on the data storage structure, and
the portion of the conductive electrode is spaced apart from a respective one of the conductive lines by the data storage structure and the channel region.

17. A memory device comprising:
a channel region;
a conductive electrode on the channel region; and
a data storage structure between the channel region and the conductive electrode,
wherein the data storage structure includes a first dielectric layer on the channel region and a second dielectric layer on the first dielectric layer,
the second dielectric layer includes a data storage region and a barrier dielectric region on the data storage region,
the data storage region includes a first material,
the barrier dielectric region includes a second material comprising a compound of the first material and oxygen or a compound of the first material and nitrogen,
a concentration of the oxygen or nitrogen in the barrier dielectric region decreases in a direction from the conductive electrode toward the channel region,
a thickness of the data storage region is in a range from 100 angstroms (Å) to 200 Å, and
a thickness of the barrier dielectric region is in a range from 5 Å to 15 Å.

18. The memory device of claim 17, wherein the first dielectric layer is in a range from 8 Å to 20 Å,
the first material comprises a ferroelectric material, and
the second material comprises a high-κ dielectric material.

19. A memory device comprising:
a channel region;
a conductive electrode on the channel region; and
a data storage structure between the channel region and the conductive electrode,
wherein the data storage structure includes a first dielectric layer in contact with the channel region, and a second dielectric layer on the first dielectric layer,
the second dielectric layer includes a ferroelectric region and a high-κ region on the ferroelectric region,
the ferroelectric region includes a first material,
the high-κ region includes a second material comprising a compound of the first material and oxygen or a compound of the first material and nitrogen, and
a concentration of the oxygen or nitrogen in the high-κ region decreases in a direction from the conductive electrode toward the channel region.

20. The memory device of claim 19, wherein a thickness of the high-κ region is in a range from 5 angstroms (Å) to 15 Å, and
the high-κ region extends from the ferroelectric region and contacts the conductive electrode.
